(19) United States
(12) Patent Application Publication
(10) Pub. No.: US 2022/0236334 A1
(43) Pub. Date: Jul. 28, 2022

(54) APPARATUS AND METHOD FOR DIAGNOSING A BATTERY FAULT

(71) Applicants: HYUNDAI MOTOR COMPANY, Seoul (KR); KIA CORPORATION, Seoul (KR)

(72) Inventors: Ki Seon Ryu, Seoul (KR); Chan Seok Choi, Seongnam-si (KR); Inho Kim, Seongnam-si (KR)

(73) Assignees: HYUNDAI MOTOR COMPANY, Seoul (KR); KIA CORPORATION, Seoul (KR)

(21) Appl. No.: 17/568,793

(22) Filed: Jan. 5, 2022

(30) Foreign Application Priority Data
Jan. 25, 2021 (KR) 10-2021-0010122

(51) Int. Cl. G01R 31/392; G01R 31/382

(52) U.S. Cl. CPC G01R 31/392; G01R 31/382

(57) ABSTRACT

Provided is an apparatus for diagnosing a battery fault, including: a communicator; and a controller electrically connected to the communicator. In particular, the controller is configured to receive history data related to a battery of a vehicle from the vehicle through the communicator, identify a history related to a decrease in a state of charge of the battery and a current consumption of the battery based on the history data, and identify whether the battery is faulty based on the identifying of the history.

### CROSS-REFERENCE TO RELATED APPLICATION

This application claims priority to and the benefit of Korean Patent Application No. 10-2021-0010122, filed on Jan. 25, 2021, the entire contents of which are incorporated herein by reference.

### BACKGROUND

### 1. Field

The present disclosure relates to an apparatus and method for diagnosing a battery fault.

### 2. Description of the Related Art

The statements in this section merely provide background information related to the present disclosure and may not constitute prior art.

An automotive battery is a component for supplying power to a starting motor to start a vehicle. When an automotive battery is discharged, a driver may not start a vehicle.

The causes of vehicle battery discharge include a malfunction of an automotive component, a misuse of an automotive component by a user (e.g., parking with the emergency lights on), abnormal current generation in an unauthorized automotive component (e.g., a fake black box, and/or a faulty battery), and the like.

When an automotive battery is discharged, a driver could not exactly know what to do to fix the battery discharge, since a cause of battery discharge could not be easily found out among the above-described causes.

When an automotive battery is discharged due to power consumption by automotive components and/or low temperatures, not a faulty battery itself, the automotive battery may be recharged by simply driving a vehicle. However, when the battery is discharged due to a battery failure itself, recharging the battery temporarily seems to fix the battery discharge, but the battery is discharged again soon.

In a conventional battery fault diagnosis technology, a battery fault may be normally diagnosed when a state of charge (SOC) of a battery is 50 percent or more. However, we have found that when the battery is completely discharged, the fault of a battery may not be diagnosed. In this case, the diagnosis of the fault of the battery is possible after charging the battery. It takes 2 or 3 hours to charge the battery, which costs a long time and also resources.

Also, in a conventional battery fault diagnosis technology, an internal resistance of a battery has been mainly measured to determine whether the battery is faulty. However, we have found that since the internal resistance of a battery varies depending on a temperature and a state of charge (SOC) of the battery, and is also different for each type of battery, a battery fault diagnosis may not be easily performed except for some failure modes. In particular, as described above, whether a battery is faulty may not be determined by measuring the internal resistance of the battery when the battery is completely discharged.

### SUMMARY

An aspect of the disclosure provides an apparatus and method for diagnosing a battery fault that may precisely diagnose a cause of discharge of a battery of a vehicle based on information acquired by a battery sensor.

For instance, the apparatus and method for diagnosing a battery fault may diagnose that the battery of the vehicle is discharged due to a fault of the battery such as a dendrite-induced short circuit in the battery and/or folding of a board of the battery when manufactured.

Additional aspects of the disclosure are set forth in part in the description which follows and, in part, will be obvious from the description, or may be learned by practice of the disclosure.

According to an aspect of the disclosure, an apparatus for diagnosing a battery fault includes: a communicator; and a controller electrically connected to the communicator, wherein the controller is configured to receive history data related to a battery of a vehicle from the vehicle through the communicator, identify a history related to a decrease in a state of charge (SOC) of the battery and a current consumption of the battery based on the history data, and identify whether the battery is faulty based on the identifying of the history.

The controller is configured to identify whether a history where the state of charge of the battery decreases exists, during a time that the history of the current consumption of the battery does not exist, based on the history data, and identify that the battery is faulty based on the identifying of the history where the state of charge of the battery decreases.

The controller is configured to identify a history where the state of charge of the battery decreases to be equal to or less than a predetermined first reference value for a predetermined period of time, and identify whether the history where the state of charge of the battery decreases exists, during the time that the history of the current consumption of the battery does not exist, before a first point in time that the state of charge of the battery decreases to be equal to or less than the predetermined first reference value for the predetermined period of time.

The controller is configured to identify a first amount of change of the state of charge of the battery based on a charge of the battery, and a second amount of change of the state of charge of the battery based on a discharge of the battery, before the first point in time for the predetermined period of time, and identify whether the history where the state of charge of the battery decreases exists, during the time that the history of the current consumption of the battery does not exist, based on the first amount of change and the second amount of change.

The controller is configured to identify that the history where the state of charge of the battery decreases exists, during the time that the history of the current consumption of the battery does not exist, based on the first amount of change being greater than a predetermined second reference value and the second amount of change being greater than a predetermined third reference value.

The first amount of change includes a value obtained by subtracting a rate of an amount of charge based on the charge from a difference value between a maximum value and a minimum value of the state of charge of the battery, for each predetermined time period, before the first point in time for the predetermined period of time, and the second amount of change includes a value obtained by subtracting a rate of an amount of discharge based on the discharge from the difference value between the maximum value and the minimum value of the state of charge of the battery, for each predetermined time period, before the first point in time for the predetermined period of time.

A fault of the battery includes a fault based on an occurrence of an internal short circuit of a board of the battery.

According to an aspect of the disclosure, a method for diagnosing a battery fault includes: receiving history data related to a battery of a vehicle from the vehicle, identifying a history related to a decrease in a state of charge (SOC) of the battery and a current consumption of the battery based on the history data, and identifying whether the battery is faulty based on the identifying of the history.

The identifying of the history includes identifying whether a history where the state of charge of the battery decreases exists, during a time that the history of the current consumption of the battery does not exist, based on the history data, and the identifying of whether the battery is faulty includes identifying that the battery is faulty based on the identifying of the history where the state of charge of the battery decreases.

The identifying of the history includes identifying a history where the state of charge of the battery decreases to be equal to or less than a predetermined first reference value for a predetermined period of time, and the identifying of whether the battery is faulty identifies whether the history where the state of charge of the battery decreases exists, during the time that the history of the current consumption of the battery does not exist, before a first point in time that the state of charge of the battery decreases to be equal to or less than the predetermined first reference value for the predetermined period of time.

The identifying of the history identifies a first amount of change of the state of charge of the battery based on a charge of the battery, and a second amount of change of the state of charge of the battery based on a discharge of the battery, before the first point in time for the predetermined period of time, and identifies whether the history where the state of charge of the battery decreases exists, during the time that the history of the current consumption of the battery does not exist, based on the first amount of change and the second amount of change.

The identifying of whether the battery is faulty identifies that the history where the state of charge of the battery decreases exists, during the time that the history of the current consumption of the battery does not exist, based on the first amount of change being greater than a predetermined second reference value and the second amount of change being greater than a predetermined third reference value.

The first amount of change includes a value obtained by subtracting a rate of an amount of charge based on the charge from a difference value between a maximum value and a minimum value of the state of charge of the battery, for each predetermined time period, before the first point in time for the predetermined period of time, and the second amount of change includes a value obtained by subtracting a rate of an amount of discharge based on the discharge from the difference value between the maximum value and the minimum value of the state of charge of the battery, for each predetermined time period, before the first point in time for the predetermined period of time.

A fault of the battery includes a fault based on an occurrence of an internal short circuit of a board of the battery.

Further areas of applicability will become apparent from the description provided herein. It should be understood that the description and specific examples are intended for purposes of illustration only and are not intended to limit the scope of the present disclosure.

### BRIEF DESCRIPTION OF THE DRAWINGS

In order that the disclosure may be well understood, there will now be described various forms thereof, given by way of example, reference being made to the accompanying drawings, in which:

FIG. 1 is a diagram illustrating a system including a vehicle and an apparatus for diagnosing a battery fault according to an embodiment;

FIG. 2 is a flowchart illustrating operations of an apparatus for diagnosing a battery fault according to an embodiment;

FIG. 3 is a flowchart of operations of an apparatus for diagnosing a battery fault according to an embodiment; and

FIG. 4 is a diagram illustrating an operation principle of an apparatus for diagnosing a battery fault according to an embodiment.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

Like reference numerals throughout the specification denote like elements. Also, this specification does not describe all the elements according to embodiments of the disclosure, and descriptions well-known in the art to which the disclosure pertains or overlapped portions are omitted. The terms such as “-part”, “-device”, “-module”, and the like may refer to a unit for processing at least one function or act. For example, the terms may refer to at least process processed by at least one hardware or software. According to embodiments, a plurality of “-parts”, “-devices”, or “-modules” may be embodied as a single element, or a single of “-part”, “-device”, or “-module” may include a plurality of elements.

It will be understood that when an element is referred to as being “connected” to another element, it can be directly or indirectly connected to the other element, wherein the indirect connection includes “connection” via a wireless communication network.

It will be understood that the terms “include” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, these elements should not be limited by these terms.

When a component, device, element, or the like of the present disclosure is described as having a purpose or performing an operation, function, or the like, the component, device, or element should be considered herein as being “configured to” meet that purpose or to perform that operation or function.

It is to be understood that the singular forms are intended to include the plural forms as well, unless the context clearly dictates otherwise.

Reference numerals used for method steps are just used for convenience of explanation, but not to limit an order of the steps. Thus, unless the context clearly dictates otherwise, the written order may be practiced otherwise.

Hereinafter, an operation principle and embodiments will be described in detail with reference to the accompanying drawings.

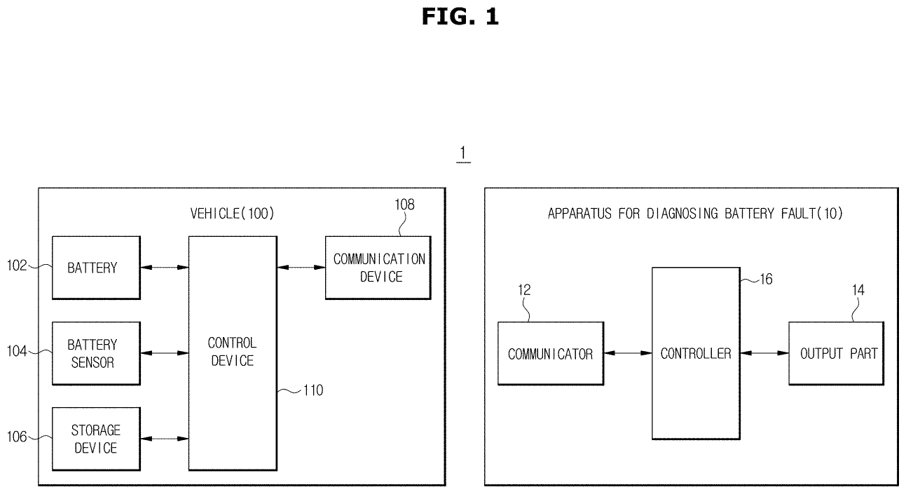

FIG. 1 is a diagram illustrating a system 1 including a vehicle 100 and an apparatus for diagnosing a battery fault 10 according to an embodiment of the present disclosure.

Referring to FIG. 1, the vehicle 100 may include a battery 102, a battery sensor 104, a storage device 106, a communication device 108 and/or a control device 110.

The battery 102 may store energy generated from power of an engine and supply electrical power to at least one of devices (also referred to as constituent components) included in the vehicle 100. For example, a generator may convert rotational energy of the engine to electric energy while driving the vehicle 100, and the battery 102 may store the electric energy supplied from the generator. Also, the battery 102 may supply electrical power for driving of the engine to a starting motor (not shown) and also supply electrical power to at least one of the devices of the vehicle 100.

When the engine is stopped, the battery 102 may supply the starting motor with electrical power for starting the engine, and also supply electrical power to at least one of the devices of the vehicle 100. For instance, the battery 102 may supply electrical power while the vehicle is parked and the engine is stopped.

The battery sensor 104 may measure (also referred to as ‘acquire’) data such as a voltage, a current, an internal resistance, a state of charge (SOC), and the like of the battery 102.

The battery sensor 104 may be mounted in the battery 102.

The storage device 106 may store the data measured by the battery sensor 104. For instance, the storage device 106 may store history data related to the battery 102 (also referred to as a state history data of the battery 102).

The history data related to the battery 102 may include information about the SOC of the battery 102, a minimum value of the internal resistance of the battery 102, a total charge value of the battery 102 and/or a total discharge value of the battery 102 for a predetermined period of time (also referred to as a first period of time).

For example, information about the SOC of the battery 102 may include information about the SOC of the battery 102 for each predetermined time period (alternatively, time interval) for the predetermined period of time. As another example, the information about the SOC of the battery 102 may include information about a corresponding time interval for each predetermined SOC interval of the battery 102 for the predetermined period of time.

For instance, the information about the SOC of the battery 102 may include information about the SOC of the battery 102 based on a charge and/or discharge of the battery 102 for the predetermined period of time.

The minimum value of the internal resistance of the battery 102 may be data for analyzing a pattern of the internal resistance of the battery 102.

The total charge value of the battery 102 may be data for analyzing a pattern of an accumulated charge amount of the battery 102.

The total discharge value of the battery 102 may be data for analyzing a pattern of an accumulated discharge amount of the vehicle 100.

The storage device 106 may store various data used by at least one device (e.g., the battery 102, the battery sensor 104, the communication device 108 and/or the control device 110) of the vehicle 100. For example, the various data may be input data or output data for a software program and instructions related thereto. The storage device 106 may include a memory (e.g., a volatile memory and/or a non-volatile memory).

The communication device 108 may establish wireless and/or wired communication channel between the vehicle 100 and an external device (e.g., the apparatus for diagnosing a battery fault 10), and support communication through the established communication channel. Also, the communication device 108 may include a communication circuit. For instance, the communication device 108 may include a wired communication module (e.g., a power line communication module) and/or a wireless communication module (e.g., a cellular communication module, a Wi-Fi communication module, a local wireless communication module, and/or a Bluetooth communication module), and may communicate with the external device using a corresponding communication module among the communication modules above.

The communication device 108 may include a control circuit for controlling an operation of a communication circuit and the communication circuit (also referred to as a transceiver) capable of performing communication among devices of the vehicle 100, e.g., a controller area network (CAN) communication and/or a local interconnect network (LIN) communication, through a communication network for vehicle 100.

The control device 110 (an integrated central control unit (ICU) or an energy management system (EMS)) may control at least one other constituent component (e.g., the battery 102, the battery sensor 104, the storage device 106 and/or the communication device 108) and/or a software (software program). Also, the control device 110 may perform various data processing and data operations.

The control device 110 may include an electronic control unit (ECU) that controls a power system of the vehicle 100.

The control device 110 may include a processor and a memory.

The control device 110 may identify history data related to the battery 102 based on the data measured by the battery sensor 104.

For example, the history data related to the battery 102 may include information about the SOC of the battery 102 for the predetermined period of time. The information about the SOC of the battery 102 may include information about the SOC of the battery 102 for each predetermined time period for the predetermined period of time. The information about the SOC of the battery 102 may include information about the SOC of the battery 102 based on charge and/or discharge of the battery 102 for the predetermined period of time.

The control device 110 may transmit the history data related to the battery 102 to the apparatus 10 for diagnosing a battery fault through the communication device 108.

The apparatus for diagnosing a battery fault 10 may include a communicator 12, an output part 14 and/or a controller 16.

The communicator 12 may establish wireless and/or wired communication channel between the apparatus for diagnosing a battery fault 10 and an external device, e.g., the vehicle 100, and support communication through the established communication channel. Also, the communicator 12 may include a communication circuit. For instance, the communicator 12 may include a wired communication module (e.g., a power line communication module) and/or a wireless communication module (e.g., a cellular communication module, a Wi-Fi communication module, a local wireless communication module, and/or a Bluetooth communication module), and may communicate with the external device using a corresponding communication module among the communication modules above.

The output part 14 may include a display capable of visually providing information to a user of the apparatus 10, a speaker capable of acoustically providing information, and the like. For instance, the display may include a touch screen capable of receiving a touch, gesture, proximity input or hovering input using a part of the user's body.

The controller 16 may control at least one component of the apparatus 10 (e.g., a hardware component such as the communicator 12 and/or the output part 14) and/or a software (software program). Also, the controller 16 may perform various data processing and data operations.

The controller 16 may receive history data related to the battery 102 of the vehicle 100 from the vehicle 100 through the communicator 12. The controller 16 may analyze a state of the battery 102 of the vehicle 100 based on the history data related to the battery 102 of the vehicle 100.

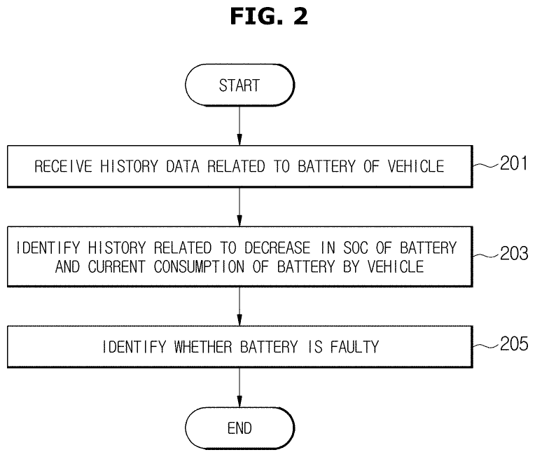

FIG. 2 is a flowchart illustrating operations of an apparatus 10 for diagnosing a battery fault (and/or the controller 16 of the apparatus for diagnosing a battery fault 10) according to an embodiment.

The apparatus 10 for diagnosing a battery fault may receive history data related to the battery 102 of the vehicle 100 from the vehicle 100 (201).

The history data related to the battery 102 of the vehicle 100 is collected for a predetermined period of time (also referred to as a first period of time). For example, the history data related to the battery 102 may include information of the SOC of the battery 102 for the predetermined period of time (e.g., for 30 days).

For instance, the information of the SOC of the battery 102 may include information about the SOC of the battery 102 for each predetermined time interval (alternatively, for each predetermined time), or information about a corresponding time interval (alternatively, time) for each predetermined SOC interval of the battery 102.

The apparatus 10 may identify a history related to a decrease in the SOC of the battery 102 and current consumption of the battery 102 by the vehicle 100 based on the history data related to the battery 102 of the vehicle 100 (203).

The apparatus 10 may determine whether the battery 102 is faulty, based on the identification of the history related to the decrease in the SOC of the battery 102 and the current consumption of the battery 102 by the vehicle 100 (205).

The apparatus 10 may determine whether there is a history that the SOC of the battery 102 decreases, during a time that a history of the current consumption of the battery 102 by the vehicle 100 does not exist based on the history data related to the battery 102 of the vehicle 100.

In general, in a battery where an internal short circuit occurs, a cell voltage is lowered, and thus a voltage does not exceed 12.0V. For example, as shown in the Table 1 below, in a battery where an internal short circuit occurs in a third battery cell, a voltage of the third battery cell is lowered, and thus a total voltage does not exceed 12.0V. Accordingly, a SOC of the battery where the internal short circuit has occurred may be measured to be 10% or less.

TABLE 1

| | First | Second | Third | Fourth | Fifth | Sixth |
|---|---|---|---|---|---|---|
| Battery | battery | battery | battery | battery | battery | battery |
| cell | cell (+) | cell | cell | cell | cell | cell (−) |
| Voltage | 1.953 | 2.156 | 0.03 | 2.153 | 2.15 | 2.149 |
| (10.58 V | | | | | | |
| in total) | | | | | | |

Based on the above, the apparatus 10 for diagnosing a battery fault may identify whether there is a history where the SOC of the battery 102 of the vehicle 100 decreases to be equal to or less than a predetermined first reference value (e.g., 10% of the full charge) before identifying the history of the current consumption of the battery 102 by the vehicle 100 and the history of decrease in SOC of the battery 102.

The apparatus 10 may identify a first point in time that the SOC of the battery 102 decreases to be equal to or less than the predetermined first reference value, based on the identification of the history where the SOC of the battery 102 of the vehicle 100 decreases to be equal to or less than a predetermined first reference value.

The apparatus 10 may identify whether there is a history where the SOC of the battery 102 of the vehicle 100 decreases to be equal to or greater than a predetermined second reference value (e.g., 20% of the full charge), in a state that the history of the current consumption of the battery 102 by the vehicle 100 does not exist before the first point in time.

The apparatus 10 for diagnosing a battery fault may determine that the battery 102 is faulty when the history where the SOC of the battery 102 decreases to be equal to or greater than a predetermined reference value during the time that the history of the current consumption of the battery 102 by the vehicle 100 does not exist.

The current consumption of the battery 102 by the vehicle 100 may be caused by an amount of dark current and/or an amount of discharge in turning on and/or off of the vehicle 100 (also referred to as IGN ON/OFF).

Considering a discharge rate of 1% due to a dark current of the vehicle 100 and a natural discharge of the battery 102 and a 10% error of the battery sensor 104, a decrease in the SOC of the battery 102 by 20% or more compared to a previous day is beyond a normal range, and may be caused by occurrence of an internal short circuit in a board of the battery 102 or performance deterioration of the battery 102. The occurrence of the internal short circuit in the board of the battery 102 and performance deterioration of the battery 102 may be distinguished by a minimum value of the SOC of the battery 102.

The apparatus 10 may determine whether the SOC of the battery 102 decreases in the state that the history of the current consumption of the battery 102 by the vehicle 100 does not exist, based on a first amount of change of the SOC of the battery 102 and a second amount of change of the SOC of the battery 102, before the first point in time. Here, the first amount of change of the SOC of the battery 102 is based on a charge of the battery 102, and the second amount of change of the SOC of the battery 102 is based on a discharge of the battery 102.

For instance, the apparatus 10 may determine that the history where the SOC of the battery 102 decreases to be equal to or less than the predetermined reference value exists, in the state that the history of current consumption of the battery 102 by the vehicle 100 does not exist, when the first amount of change is greater than the predetermined second reference value and the second amount of change is greater than a predetermined third reference value, before the first point in time. Here, the first amount of change of the SOC of the battery 102 is based on the charge of the battery 102, and the second amount of change of the SOC of the battery 102 is based on the discharge of the battery 102.

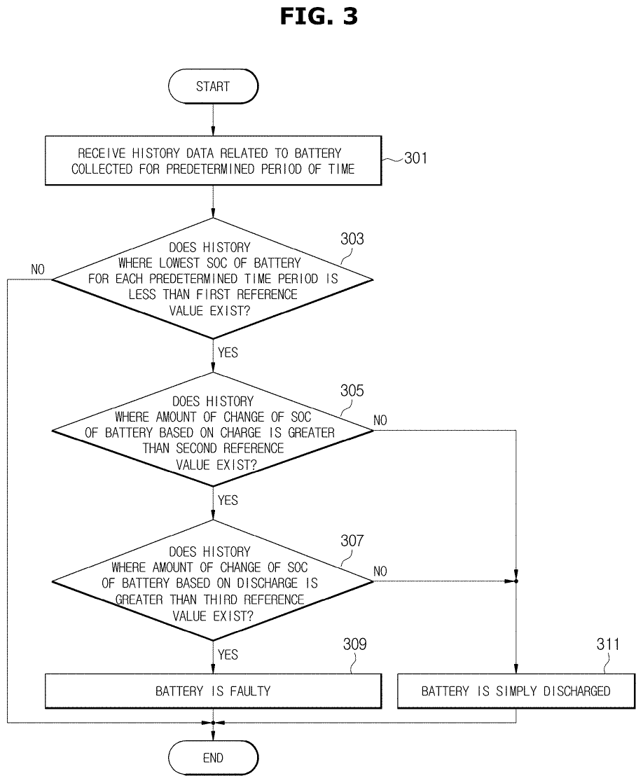

FIG. 3 is a flowchart of operations of an apparatus for diagnosing a battery fault 10 (and/or the controller 16 of the apparatus for diagnosing a battery fault 10) according to an embodiment.

The apparatus for diagnosing a battery fault 10 may receive history data related to the battery 102 collected for a predetermined period of time (e.g., 30 days) from the vehicle 100 (301).

The apparatus for diagnosing a battery fault 10 may identify whether a history where a lowest SOC of the battery 102 for each predetermined time period (e.g., per day) for a predetermined period of time is less than a first reference value (e.g. 10%) exists, based on the history data (303).

When the history where the lowest SOC of the battery 102 for each predetermined time period is less than the first reference value exists, the apparatus for diagnosing a battery fault 10 performs an operation 305. Otherwise, the apparatus for diagnosing a battery fault 10 may end an operation according to an embodiment.

The apparatus for diagnosing a battery fault 10 may identify whether a history where an amount of change of a SOC of the battery 102 based on a charge of the battery 102 is greater than a second reference value (e.g., 20%) exists, based on the history data (305).

The apparatus for diagnosing a battery fault 10 may identify whether the history where the amount of change of the SOC of the battery 102 based on the charge of the battery 102 is greater than the second reference value exists, before a point in time (also referred to as a first point in time) that the lowest SOC of the battery 102 is less than the first reference value.

For example, the apparatus for diagnosing a battery fault 10 may identify whether the history where the amount of change (also referred to as a first amount of change) of the SOC of the battery 102 based on the charge of the battery 102 is greater than the second reference value exists, based on Equation 1 below:

A first amount of change=(a maximum SOC−a minimum SOC)−(a rate of an amount of charge based on charge). [Equation 1]

When the history where the amount of change of the SOC of the battery 102 based on the charge of the battery 102 is greater than the second reference value exists, the apparatus for diagnosing a battery fault 10 performs an operation 307. Otherwise, the apparatus for diagnosing a battery fault 10 may perform an operation 311.

The apparatus for diagnosing a battery fault 10 may identify whether a history where an amount of change of a SOC of the battery 102 based on a discharge of the battery 102 is greater than a third reference value (e.g. 20%) exists, based on the history data (307).

The apparatus for diagnosing a battery fault 10 may identify whether the history where the amount of change of the SOC of the battery 102 based on the discharge of the battery 102 is greater than the third reference value exists, before the point in time that the lowest SOC of the battery 102 is less than the first reference value.

For example, the apparatus for diagnosing a battery fault 10 may identify whether the history where the amount of change (also referred to as a second amount of change) of the SOC of the battery 102 based on the discharge of the battery 102 is greater than the third reference value exists, based on Equation 2 below:

A second amount of change=(a maximum SOC−a minimum SOC)−(a rate of an amount of discharge based on discharge). [Equation 2]

When the history where the amount of change of the SOC of the battery 102 based on the discharge of the battery 102 is greater than the third reference value exists, the apparatus for diagnosing a battery fault 10 performs an operation 309. Otherwise, the apparatus for diagnosing a battery fault 10 may perform an operation 311.

The apparatus for diagnosing a battery fault 10 may identify that the battery 102 is faulty (309).

The apparatus for diagnosing a battery fault 10 may identify that a fault of the battery 102 is caused by an internal short circuit of a board of the battery 102.

The apparatus for diagnosing a battery fault 10 may identify that the battery 102 is simply discharged (311).

The apparatus for diagnosing a battery fault 10 may identify that the battery 102 is not faulty.

Meanwhile, although it has been described above that the operation 307 is performed after the operation 305, the operation 305 may be performed after the operation 307 or the operation 305 and the operation 307 may be performed in parallel, according to another embodiment.

For example, the apparatus for diagnosing a battery fault 10 may perform the operation 305, when the history where the amount of change of the SOC of the battery 102 based on the discharge of the battery 102 is greater than the third reference value exists through performing the operation 307. Otherwise, the apparatus for diagnosing a battery fault 10 may perform the operation 311. Also, the apparatus for diagnosing a battery fault 10 may perform the operation 309, when the history where the amount of change of the SOC of the battery 102 based on the charge of the battery 102 is greater than the second reference value exists through performing the operation 305. Otherwise, the apparatus for diagnosing a battery fault 10 may perform the operation 311.

As another example, the apparatus for diagnosing a battery fault 10 may perform the operation 305 and the operation 307 in parallel. That is, the apparatus for diagnosing a battery fault 10 may perform the operation 309, when the history where the amount of change of the SOC of the battery 102 based on the charge of the battery 102 is greater than the second reference value exists through performing the operation 305 and the history where the amount of change of the SOC of the battery 102 based on the discharge of the battery 102 is greater than the third reference value exists through performing the operation 307. Otherwise, the apparatus for diagnosing a battery fault 10 may perform the operation 311.

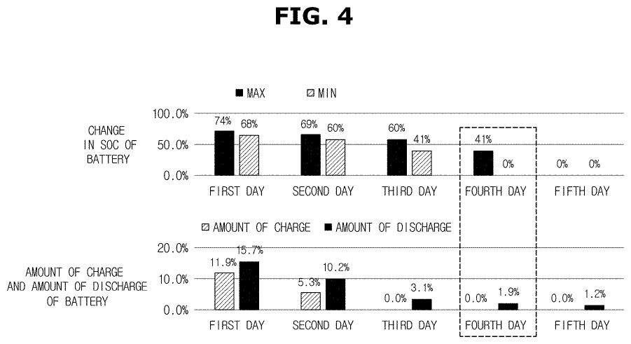

FIG. 4 is a diagram illustrating an operation principle of an apparatus for diagnosing a battery fault 10 according to an embodiment.

Referring to FIG. 4, a change in a SOC of the battery 102 by an amount of charge (also referred to as a rate of an amount of charge) and an amount of discharge (also referred to as a rate of an amount of discharge) of the battery 102 for the first two days may be confirmed. However, on the third day, even when a discharge of the battery 102 is minute, it may be confirmed that a SOC of the battery 102 tends to decrease by approximately 20% or more, and a minimum value of the SOC decreases to 0% on the fourth day.

It may be confirmed that the SOC decreases by 6% and an amount of discharge is generated by approximately 4% for the first day, and the SOC decreases by 9% and the amount of discharge is generated by approximately 5% for the second day. Accordingly, it may be confirmed that a maximum error between a maximum value and a minimum value of the SOC may be approximately 10%.

Referring to FIG. 4, the SOC is reduced by an internal short circuit of the battery 102 between the third day and the fourth day. According to an embodiment, a final internal short circuit of the battery 102 may be identified based on history data for four days.

The above-described embodiments may be applied to a diagnosis of the battery 102 when the battery 102 of the vehicle 100 is discharged or a user visits a car repair shop due to the SOC of the battery 102.

As is apparent from the above, according to the embodiment of the disclosure, the apparatus and method for diagnosing a battery fault can precisely diagnose a cause of discharge of the battery of the vehicle.

Although various apparatuses for diagnosing a battery fault have been proposed in a conventional art, a cause of discharge of a battery has been incorrectly diagnosed in many cases, resulting in wasteful car maintenance. To overcome the disadvantage, the apparatus and method for diagnosing a battery fault according to the embodiment of the disclosure can precisely diagnose whether discharge of the battery is caused by an internal short circuit of the battery or an external malfunction based on data measured by a battery sensor. Accordingly, the apparatus and method for diagnosing a battery fault can rapidly diagnose whether the discharged battery is faulty, resulting in a reduced diagnostic time and an improvement of accuracy of diagnose. Further, the apparatus and method for diagnosing a battery fault according to the embodiment of the disclosure can reduce a cost for purchasing a battery diagnosis apparatus, since a separate battery diagnosis apparatus is not required.

Embodiments can thus be implemented through computer readable code/instructions in/on a medium, e.g., a computer readable medium, to control at least one processing element to implement any above described exemplary embodiment. The medium can correspond to any medium/media permitting the storing and/or transmission of the computer readable code.

The computer-readable code can be recorded on a medium or transmitted through the Internet. The medium may include Read Only Memory (ROM), Random Access Memory (RAM), magnetic tapes, magnetic disks, flash memories, and optical recording medium.

Although embodiments have been described for illustrative purposes, those having ordinary skill in the art will appreciate that various modifications, additions and substitutions are possible, without departing from the scope and spirit of the present disclosure. Therefore, embodiments have not been described for limiting purposes.

What is claimed is:

1. An apparatus for diagnosing a battery fault, comprising:
a communicator; and
a controller electrically connected to the communicator,
wherein the controller is configured to:
receive history data related to a battery of a vehicle through the communicator,
identify a history related to a decrease in a state of charge (SOC) of the battery and a current consumption of the battery based on the history data, and
identify whether the battery is faulty based on the identified history.

2. The apparatus of claim 1, wherein the controller is further configured to:
determine whether there is a history that the SOC of the battery decreases during a time that the history of the current consumption of the battery does not exist based on the history data, and
determine that the battery is faulty based on the identified history of decrease in the SOC of the battery during the time.

3. The apparatus of claim 2, wherein the controller is configured to identify a history where the SOC of the battery decreases to be equal to or less than a
predetermined first reference value for a predetermined period of time, and determine whether there is the history that the SOC of the battery decreases before a first point in time that the SOC of the battery decreases to be equal to or less than the predetermined first reference value for the predetermined period of time.

4. The apparatus of claim 3, wherein the controller is configured to identify a first amount of change of the SOC of the battery based on a charge of the battery, and a second amount of change of the SOC of the battery based on a discharge of the battery before the first point in time for the predetermined period of time, and
determine whether there is the history that the SOC of the battery decreases during the time based on the first amount of change and the second amount of change.

5. The apparatus of claim 4, wherein the controller is configured to determine that the history where the SOC of the battery decreases exists during the time when the first amount of change is greater than a predetermined second reference value and the second amount of change is greater than a predetermined third reference value.

6. The apparatus of claim 4, wherein the first amount of change comprises a value obtained by subtracting a rate of an amount of charge based on the charge from a difference value between a maximum value and a minimum value of the SOC of the battery, for each predetermined time period, before the first point in time for the predetermined period of time, and
the second amount of change comprises a value obtained by subtracting a rate of an amount of discharge based on the discharge from the difference value between the maximum value and the minimum value of the SOC of the battery, for each predetermined time period, before the first point in time for the predetermined period of time.

7. The apparatus of claim 1, wherein a fault of the battery comprises a fault caused by an occurrence of an internal short circuit of a board of the battery.

8. A method for diagnosing a battery fault, the method comprising:
receiving history data related to a battery of a vehicle from the vehicle,
identifying a history related to a decrease in a state of charge (SOC) of the battery and a current consumption of the battery based on the history data, and
determining whether the battery is faulty based on the identified history.

9. The method of claim 8, wherein:
identifying the history comprises identifying, based on the history data, whether a history where the SOC of the battery decreases exists during a time that the history of the current consumption of the battery does not exist, and
determining whether the battery is faulty comprises identifying that the battery is faulty based on the identified history where the SOC of the battery decreases.

10. The method of claim 9, wherein:
identifying the history comprises identifying a history where the SOC of the battery decreases to be equal to or less than a predetermined first reference value for a predetermined period of time, and
determining whether the battery is faulty identifies whether the history where the SOC of the battery decreases exists during the time before a first point in time that the SOC of the battery decreases to be equal to or less than the predetermined first reference value for the predetermined period of time.

11. The method of claim 10, wherein identifying the history includes: identifying a first amount of change of the SOC of the battery based on a charge of the battery, and a second amount of change of the SOC of the battery based on a discharge of the battery, before the first point in time for the predetermined period of time, and
determining whether the history where the SOC of the battery decreases exists during the time based on the first amount of change and the second amount of change.

12. The method of claim 11, wherein determining whether the battery is faulty includes: identifying that the history where the SOC of the battery decreases exists during the time when the first amount of change is greater than a predetermined second reference value and the second amount of change is greater than a predetermined third reference value.

13. The method of claim 11, wherein the first amount of change comprises a value obtained by subtracting a rate of an amount of charge based on the charge from a difference value between a maximum value and a minimum value of the SOC of the battery, for each predetermined time period, before the first point in time for the predetermined period of time, and
the second amount of change comprises a value obtained by subtracting a rate of an amount of discharge based on the discharge from the difference value between the maximum value and the minimum value of the SOC of the battery, for each predetermined time period, before the first point in time for the predetermined period of time.

14. The method of claim 8, wherein a fault of the battery comprises a fault caused by an occurrence of an internal short circuit of a board of the battery.
